(19) United States
(12) Patent Application Publication
(10) Pub. No.: US 2012/0153289 A1
(43) Pub. Date: Jun. 21, 2012

(54) SEMICONDUCTOR DEVICE, ACTIVE MATRIX SUBSTRATE, AND DISPLAY DEVICE

(75) Inventor: Seiji Kaneko, Osaka (JP)

(73) Assignee: SHARP KABUSHIKI KAISHA, Osaka (JP)

(21) Appl. No.: 13/393,130

(22) PCT Filed: Aug. 26, 2010
(86) PCT No.: PCT/JP2010/064447

§ 371 Date: Feb. 28, 2012

(30) Foreign Application Priority Data
Sep. 1, 2009 (JP) 2009-201367

(51) Int. Cl. H01L 33/08; H01L 29/786

(52) U.S. Cl. 257/59; 257/72; 257/E33.012; 257/E29.273

(57) ABSTRACT

A semiconductor device which can achieve an increase in ON current and which can also achieve a reduction in leak current and an active matrix substrate and a display device using such a semiconductor device are provided. In a switching element (semiconductor device) (18) having a top gate electrode (21)and a bottom gate electrode (23), this switching element includes a silicon layer (semiconductor layer) (SL) provided between the top gate electrode (21)and the bottom gate electrode (light-shielding film) (23)and having a source region (24), a drain region (28), a channel region (26), and low-concentration impurity regions (25 and 27). Furthermore, the bottom gate electrode (23)is provided below regions of the silicon layer (SL) that become depletion regions, and at the bottom gate electrode (23), the potential thereof is controlled so as to be a specified potential.

### TECHNICAL FIELD

The present invention relates to a semiconductor device including a transistor, as well as an active matrix substrate and a display device using this semiconductor device.

### BACKGROUND ART

Liquid crystal display devices, for example, have been widely utilized in recent years in liquid crystal televisions, monitors, mobile phones, and the like as flat panel displays having characteristic features such as a low profile and light weight compared to conventional cathode-ray tube display devices. Among such liquid crystal display devices, known devices use, in a liquid crystal panel as the display panel, an active matrix substrate in which a plurality of data wiring lines (source wiring lines) and a plurality of scan wiring lines (gate wiring lines) are arranged in a matrix, and pixels having switching elements such as thin-film transistors (hereinafter abbreviated as “TFTs”) and pixel electrodes connected to these switching elements are disposed in a matrix in the vicinity of the intersections of the data wiring lines and the scan wiring lines.

Furthermore, on an active matrix substrate such as the ones described above, thin-film transistors for peripheral circuitry are integrally provided in general besides thin-film transistors for driving the pixels used as the aforementioned switching elements. Moreover, in cases where an active matrix substrate is used in a liquid crystal display device equipped with a touch panel, a liquid crystal display device equipped with an illuminance sensor (ambient sensor), or the like, it has been proposed that photodiodes (thin-film diodes; TFDs) as optical sensors be provided integrally on this active matrix substrate in addition to the aforementioned thin-film transistors for peripheral circuitry and for driving the pixels. Thus, semiconductor devices including a plurality of thin-film transistors and photodiodes are used in an active matrix substrate.

In addition, with semiconductor devices such as the ones described above, there has been a demand for reducing leak current of thin-film transistors (transistors) in the aforementioned liquid crystal panels with a built-in optical sensor, liquid crystal panels with a built-in pixel memory, or the like in order to meet the demand for lower power consumption.

In light of this, with a conventional semiconductor device, it has been proposed to reduce leak current by providing a light-shielding film below a transistor and shielding illumination light from the backlight device as described in Japanese Patent Application Laid-Open Publication No. H8-62579, for example. In this conventional semiconductor device, furthermore, as a result of a light-shielding film being configured of an electrically conductive material, this light-shielding film is used as a bottom gate electrode. Moreover, in this conventional semiconductor device, the application of a potential lower than the gate selection potential and higher than the gate non-selection potential to the aforementioned bottom gate electrode (light-shielding film) has made it possible to reduce leak current caused by parasitic capacitance of the silicon layer (semiconductor layer) on the side of the channel back surface (on the side of the bottom gate electrode of the channel region).

### SUMMARY OF THE INVENTION

### Problems to be Solved by the Invention

However, in a conventional semiconductor device such as the one described above, the bottom gate electrode is provided so as to cover the entire surface of the silicon layer below this silicon layer. For this reason, the potential of the bottom gate electrode affects not only the channel region but also the source region and drain region provided in the silicon layer in this conventional semiconductor device. As a result, in this conventional semiconductor device, in each of the states thereof, i.e., in an ON state and OFF state, appropriate voltage cannot be applied to each of the regions of the silicon layer, so problems arise in that the ON current (current drive power) cannot be increased and that the (OFF) leak current cannot be reduced.

In light of the aforementioned problems, the present invention has its object to provide a semiconductor device which can achieve an increase in ON current and which can also achieve a reduction in leak current, as well as an active matrix substrate and a display device using this semiconductor device.

In order to achieve the aforementioned object, the semiconductor device according to the present invention is a semiconductor device including a thin-film transistor having a top gate electrode and a bottom gate electrode, wherein this semiconductor device includes a semiconductor layer provided between the top gate electrode and the bottom gate electrode and having a source region, a drain region, and a channel region, the bottom gate electrode is provided below a region of the semiconductor layer that becomes a depletion region, and the potential of the bottom gate electrode is controlled so as to be within a specified range.

The present invention makes it possible to provide a semiconductor device which can achieve an increase in ON current and which can also achieve a reduction in leak current, as well as an active matrix substrate and a display device using this semiconductor device.

### BRIEF DESCRIPTION OF THE DRAWINGS

FIG. 1 is a diagram illustrating the liquid crystal display device according to a first embodiment of the present invention.

FIG. 2 is a diagram illustrating the configuration of the liquid crystal panel shown in FIG. 1.

FIG. 3 is a plan view showing the configuration of principal parts of one of the switching elements shown in FIG. 2.

FIG. 4 is a sectional view showing the concrete configuration of the aforementioned switching element.

FIG. 5 constitutes a diagram illustrating manufacturing steps of the aforementioned switching element; FIGS. 5(a) to 5(d) illustrate a series of main manufacturing steps.

FIG. 6 constitutes a diagram illustrating manufacturing steps of the aforementioned switching element; FIGS. 6(a) to 6(c) illustrate a series of main manufacturing steps performed following the completion of the step shown in FIG. 5(d).

FIG. 7 constitutes a diagram illustrating manufacturing steps of the aforementioned switching element; FIGS. 7(a) to 7(c) illustrate a series of main manufacturing steps performed following the completion of the step shown in FIG. 6(c).

FIG. 8 constitutes a diagram illustrating manufacturing steps of the aforementioned switching element; FIGS. 8(a) and 8(b) illustrate a series of main manufacturing steps performed following the completion of the step shown in FIG. 7(c).

FIG. 9 is a graph showing the relationship between the top gate voltage and the drain current in a product of the present embodiment and in a conventional product.

FIG. 10 is a plan view showing the configuration of principal parts of the switching element according to a second embodiment of the present invention.

### DETAILED DESCRIPTION OF EMBODIMENTS

The semiconductor device according to one embodiment of the present invention is a semiconductor device including a thin-film transistor having a top gate electrode and a bottom gate electrode, wherein a semiconductor layer is provided between the top gate electrode and the bottom gate electrode, and has a source region, a drain region, and a channel region, the bottom gate electrode is provided below a region of the semiconductor layer that is to become a depletion region, and a potential of the bottom gate electrode is controlled so as to be within a specified range (first configuration).

In the first configuration, the potential of the bottom gate electrode provided below a region of the semiconductor layer that becomes a depletion region is controlled so as to be within a specified range. Consequently, unlike the aforementioned prior art, it is possible to configure a semiconductor device which can achieve an increase in ON current and which can also achieve a reduction in leak current.

Furthermore, in the first configuration, the bottom gate electrode preferably has a light shielding property (second configuration).

In this case, unlike the aforementioned prior art, the bottom gate electrode having light shielding properties is provided below only the junction region (carrier generation region) that induces the (OFF) leak current by photoelectric effect. As a result, it is possible to reduce leak current caused by light irradiation. Moreover, it is possible to prevent the structure of the semiconductor device from becoming complex and larger in size, compared to the case of separately providing a light-shielding film. In addition, a semiconductor device that is simple to manufacture can be configured easily.

Furthermore, in the first or second configuration, low-concentration impurity regions may be respectively provided in the semiconductor layer between the source region and the channel region and between the channel region and the drain region, and the bottom gate electrode may be provided below the low-concentration impurity regions, a portion of the source region, a portion of the drain region, and portions of the channel region toward the low-concentration impurity regions, which are to become the depletion regions (third configuration).

By combining with the second configuration, in particular, the bottom gate electrode having light shielding properties is provided below the low-concentration impurity regions used as the depletion regions, a portion of the source region, a portion of the drain region, and portions of the channel region toward the low-concentration impurity regions. This makes it possible to prevent these depletion regions from being irradiated with light. As a result, the leak current can be reliably reduced.

Moreover, in the third configuration, at the bottom gate electrode, it is preferable that the potential of the bottom gate electrode be controlled such that the low-concentration impurity region is in a depletion state when the thin-film transistor is in an OFF state, and that the potential of the bottom gate electrode be controlled such that the low-concentration impurity region is in an accumulation state when the thin-film transistor is in an ON state (fourth configuration).

In this case, the ON current can be reliably increased, and the leak current can be reliably reduced.

In addition, in any one of the first to fourth configurations, at the top gate electrode, the potential of the top gate electrode may be controlled by a gate signal from first signal wiring connected to the top gate electrode, and at the bottom gate electrode, the potential of the bottom gate electrode may be controlled by capacitance coupling with the top gate electrode (fifth configuration).

In this case, the potential of the bottom gate electrode is controlled by capacitance coupling with the top gate electrode. This makes it possible to omit the installation of signal wiring or the like for applying a specified potential to the bottom gate electrode. As a result, a semiconductor device with a simple structure can be configured easily.

Furthermore, in any one of the first to fourth configurations, at the top gate electrode, the potential of the top gate electrode may be controlled by a gate signal from first signal wiring connected to this top gate electrode, and at the bottom gate electrode, the potential of the bottom gate electrode may be controlled by a bottom gate signal from second signal wiring connected to the bottom gate electrode (sixth configuration).

In this case, the potential of the bottom gate electrode is controlled by a bottom gate signal from second signal wiring connected to the bottom gate electrode. Consequently, control can be performed with a higher degree of freedom with respect to the potential of this bottom gate electrode. As a result, it becomes possible to achieve an increase in ON current and a reduction in leak current more easily.

Moreover, the active matrix substrate according to one embodiment of the present invention uses any of the aforementioned semiconductor devices (seventh configuration).

In the active matrix substrate configured as described above, a semiconductor device is used which can achieve an increase in ON current and which can also achieve a reduction in leak current. As a result, it is possible to easily configure an active matrix substrate with high performance and lower power consumption.

In addition, the display device according to one embodiment of the present invention uses any of the aforementioned semiconductor devices (eighth configuration).

In the display device configured as described above, a semiconductor device is used which can achieve an increase in ON current and which can also achieve a reduction in leak current. As a result, it is possible to easily configure a display device with high performance and lower power consumption.

Preferred embodiments of the semiconductor device, active matrix substrate, and display device of the present invention will be described below while referring to drawings. Note that the following description is given by exemplifying a case in which the present invention is applied to switching elements for pixel electrodes used in an active matrix substrate. Furthermore, the dimensions of the structural members in each figure are not faithful representations of the dimensions of actual structural members, the dimensional ratios of the respective structural members, or the like.

### First Embodiment

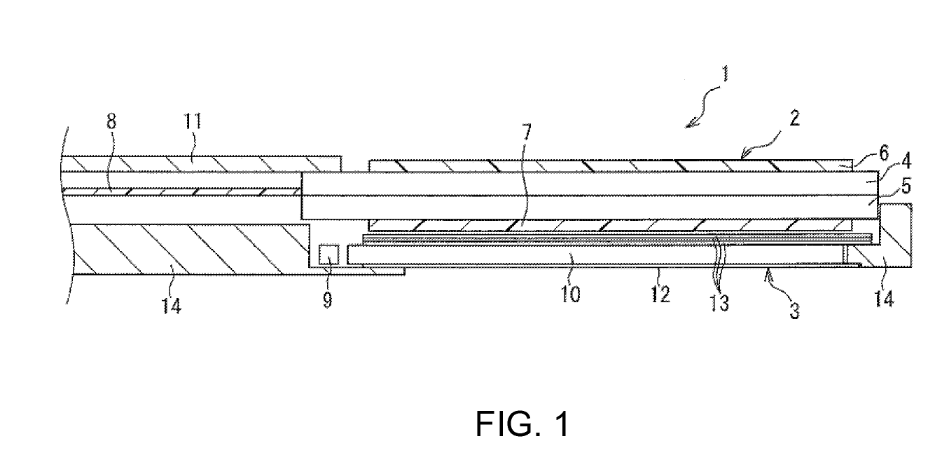

FIG. 1 is a diagram illustrating the liquid crystal display device according to a first embodiment of the present invention. In FIG. 1, the liquid crystal display device 1 of the present embodiment includes a liquid crystal panel 2 installed with the upper side in FIG. 1 being the viewer's side (display surface side) and a backlight device 3 which is disposed on the non-display surface side (lower side in FIG. 1) of the liquid crystal panel 2 and which emits illumination light that irradiates this liquid crystal panel 2.

The liquid crystal panel 2 includes a color filter substrate 4 and an active matrix substrate 5 that make up a pair of substrates and polarizing plates 6 and 7 that are respectively provided on the outer surfaces of the color filter substrate 4 and the active matrix substrate 5. A liquid crystal layer (omitted from the illustration) is sandwiched between the color filter substrate 4 and the active matrix substrate 5. Furthermore, a flat plate-form transparent glass material or transparent synthetic resin such as acrylic resin is used for the color filter substrate 4 and the active matrix substrate 5. Resin film of triacetylcellulose (TAC), polyvinyl alcohol (PVA), or the like is used for the polarizing plates 6 and 7. Each of the polarizing plates 6 and 7 is affixed to the corresponding one of the color filter substrate 4 and active matrix substrate 5 so as to cover at least the effective display region of the display surface provided on the liquid crystal panel 2.

Moreover, the active matrix substrate 5 constitutes one of the substrates of the aforementioned pair of substrates. The active matrix substrate 5 has pixel electrodes, thin-film transistors (TFTs), and the like formed thereon between this substrate and the aforementioned liquid crystal layer so as to correspond to the plurality of pixels contained in the display surface of the liquid crystal panel 2 (a detail to be described later). In addition, as will be described later, switching elements (semiconductor devices) of the present invention including the aforementioned thin-film transistors are provided in pixel units on this active matrix substrate 5. Meanwhile, the color filter substrate 4 constitutes the other substrate of the pair of substrates. The color filter substrate 4 has a color filter, an opposite electrode, and the like formed thereon between this substrate and the aforementioned liquid crystal layer (not illustrated).

Furthermore, the liquid crystal panel 2 is provided with a flexible printed circuit (FPC) 8 connected to a control device (not illustrated) that controls the driving of this liquid crystal panel 2. In the liquid crystal panel 2, the aforementioned liquid crystal layer is operated in pixel units. Consequently, the display surface is driven in pixel units. As a result, a desired image is displayed on this display surface.

Note that the liquid crystal mode and pixel structure of the liquid crystal panel 2 are arbitrary. Moreover, the drive mode of the liquid crystal panel 2 is also arbitrary. That is, any liquid crystal panel that can display information can be used as the liquid crystal panel 2. Therefore, a detailed structure of the liquid crystal panel 2 is not illustrated in FIG. 1, and a description thereof is also omitted.

The backlight device 3 includes a light-emitting diode 9 as the light source and a light guide plate 10 disposed facing the light-emitting diode 9. In addition, in the backlight device 3, the light-emitting diode 9 and the light guide plate 10 are held in by a bezel 14 having a sectional L shape in a state in which the liquid crystal panel 2 is installed over the light guide plate 10. Furthermore, a case 11 is carried on the color filter substrate 4. Consequently, the backlight device 3 is assembled to the liquid crystal panel 2 and integrated with the liquid crystal panel 2. As a result, a transmissive liquid crystal display device 1 in which illumination light from this backlight device 3 is caused to be incident on the liquid crystal panel 2 is constituted.

Synthetic resin such as transparent acrylic resin, for example, is used for the light guide plate 10. Light from the light-emitting diode 9 enters the light guide plate 10. A reflective sheet 12 is installed on the light guide plate 10 on the side opposite (opposite surface side) from the liquid crystal panel 2. Moreover, optical sheets 13 such as a lens sheet and diffusion sheet are provided on the light guide plate 10 on the side of the liquid crystal panel 2 (on the light-emitting surface side). Consequently, light from the light-emitting diode 9 guided in a specified guide direction (in the direction from left to right in FIG. 1) inside the light guide plate 10 is changed to the aforementioned illumination light having a planar shape and uniform luminance, and is supplied to the liquid crystal panel 2.

Note that in the aforementioned description, a configuration was described which uses an edge-light-type backlight device 3 having the light guide plate 10. However, the present embodiment is not limited to this. A direct-type backlight device may also be used as the backlight device 3. In addition, it is also possible to use a backlight device having another light source such as a cold cathode fluorescent lamp or hot cathode fluorescent lamp other than the light-emitting diode.

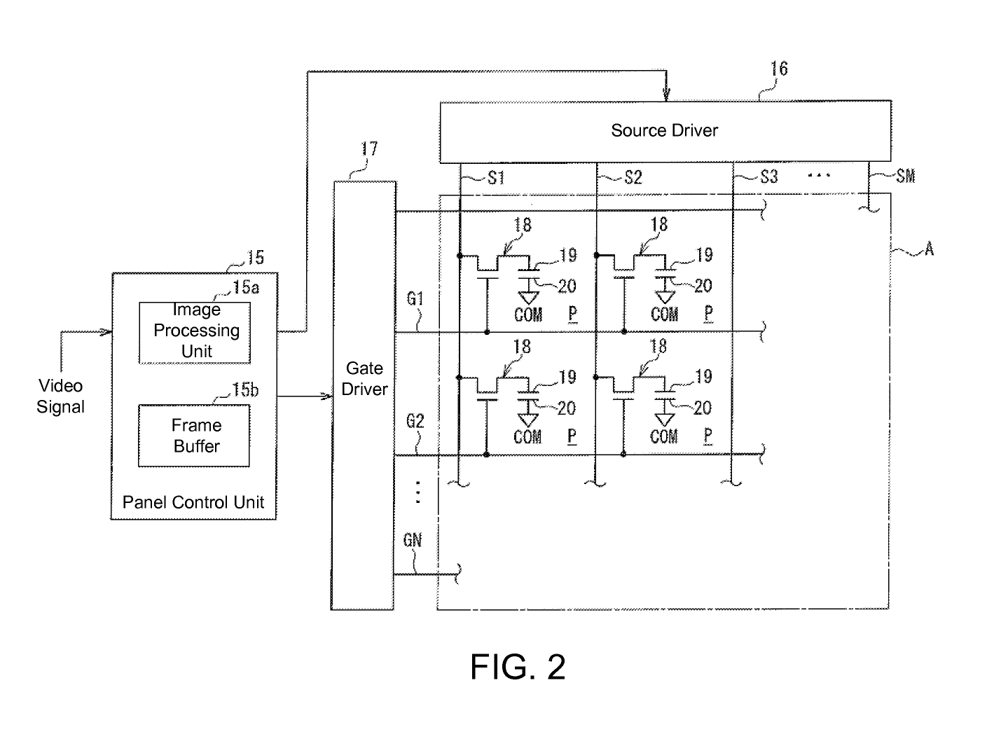

Next, the liquid crystal panel 2 of the present embodiment will be described in concrete terms with reference to FIG. 2 as well.

FIG. 2 is a diagram illustrating the configuration of the liquid crystal panel shown in FIG. 1.

In FIG. 2, the liquid crystal display device 1 (FIG. 1) is provided with a panel control unit 15, a source driver 16, and a gate driver 17. The panel control unit 15 controls the driving of the liquid crystal panel 2 (FIG. 1) used as the aforementioned display unit that displays information such as characters and images. The source driver 16 and the gate driver 17 operate based on command signals from the panel control unit 15.

The panel control unit 15 is provided inside the aforementioned control device. The panel control unit 15 is designed such that a video signal from outside of the liquid crystal display device 1 is input. Furthermore, the panel control unit 15 includes an image processing unit 15a and a frame buffer 15b. The image processing unit 15a subjects the input video signal to specified image processing and generates respective command signals for the source driver 16 and the gate driver 17. The frame buffer 15b can store one frame of display data contained in the input video signal. Then, as a result of the panel control unit 15 controlling the driving of the source driver 16 and the gate driver 17 in accordance with the input video signal, information corresponding to the input video signal is displayed on the liquid crystal panel 2.

The source driver 16 and the gate driver 17 are installed on the active matrix substrate 5. In concrete terms, the source driver 16 is installed on the surface of the active matrix substrate 5 in the outer region of the aforementioned effective display region A of the liquid crystal panel 2 used as the display panel along the horizontal direction of this liquid crystal panel 2. Moreover, the gate driver 17 is installed on the surface of the active matrix substrate 5 in the outer region of the aforementioned effective display region A along the vertical direction of this liquid crystal panel 2.

In addition, the source driver 16 and the gate driver 17 are driver circuits that drive a plurality of pixels P provided on the side of the liquid crystal panel 2 in pixel units. A plurality of source wiring lines S1 to SM (M is an integer that is two or more; hereinafter collectively referred to as “S”) and a plurality of gate wiring lines G1 to GN (N is an integer that is two or more; hereinafter collectively referred to as “G”) are respectively connected to the source driver 16 and the gate driver 17. These source wiring lines S and gate wiring lines G respectively constitute data wiring and scan wiring. Furthermore, these source wiring lines S and gate wiring lines G are arranged in a matrix so as to intersect with each other on a base material (not illustrated) made of a transparent glass material or transparent synthetic resin contained in the active matrix substrate 5. Specifically, the source wiring lines S are provided on the aforementioned base material so as to be parallel to the column direction of the matrix (vertical direction of the liquid crystal panel 2). The gate wiring lines G are provided on the aforementioned base material so as to be parallel to the row direction of the matrix (horizontal direction of the liquid crystal panel 2).

Moreover, these gate wiring lines G constitute first signal wiring. As a result of a gate signal being supplied to one of these gate wiring lines G, the potential of the top gate electrode (described later) of the corresponding ones of the aforementioned switching elements is controlled.

In addition, the aforementioned pixels P having the switching elements 18 for pixel electrodes using the semiconductor device of the present invention and pixel electrodes 19 connected to the switching elements 18 are provided in the vicinity of the intersections of these source wiring lines S and gate wiring lines G. Furthermore, in the respective pixels P, a common electrode 20 is provided so as to face the pixel electrodes 19 in a state in which the liquid crystal layer provided on the liquid crystal panel 2 is sandwiched therebetween. That is, on the active matrix substrate 5, the switching elements 18 and the pixel electrodes 19 are respectively provided in pixel units. The common electrode 20 is provided as an electrode that is common to all of the pixels.

Moreover, a region for each of the plurality of pixels P is formed in each of the regions compartmentalized in a matrix by the source wiring lines S and the gate wiring lines G on the active matrix substrate 5. Red (R), green (G), and blue (B) pixels are contained in such a plurality of pixels P. In addition, these RGB pixels are arranged sequentially in this order, for example, in parallel to the respective gate wiring lines G1 to GN. Furthermore, these RGB pixels are designed to be able to display the corresponding colors by means of a color filter layer (described later) provided on the side of the color filter substrate 4.

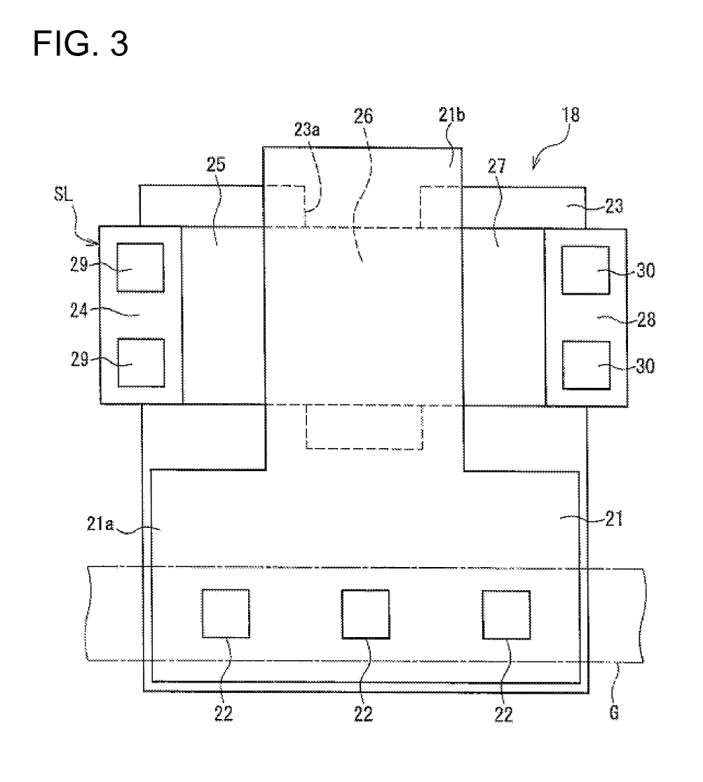

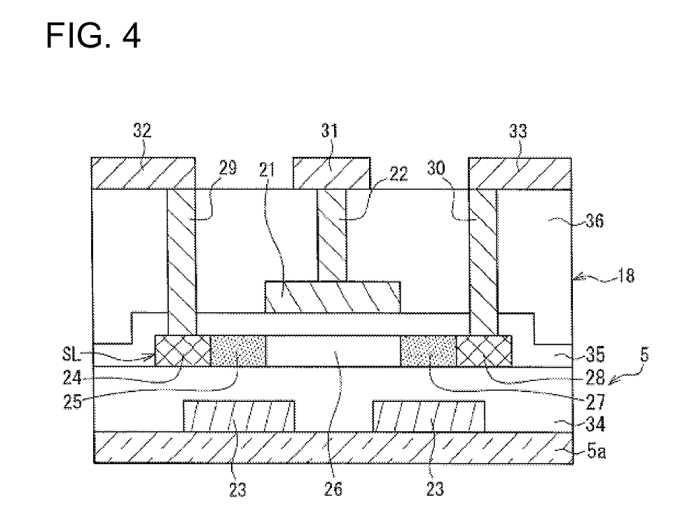

Moreover, on the active matrix substrate 5, the gate driver 17 sequentially outputs to the gate wiring lines G1 to GN scan signals (gate signals) that place the gate electrodes 31 (see FIG. 4) and top gate electrodes 21 (see FIGS. 3 and 4) of the corresponding switching elements 18 in an ON state on the basis of the command signals from the image processing unit 15a. In addition, the source driver 16 outputs to the corresponding source wiring lines S1 to SM data signals (voltage signals (grayscale voltage)) corresponding to the luminance (grayscale) of the displayed image on the basis of the command signals from the image processing unit 15a.

Next, the switching elements 18 of the present embodiment will be described in concrete terms with reference to FIGS. 3 and 4.

FIG. 3 is a plan view showing the configuration of principal parts of one of the switching elements 18 shown in FIG. 2. FIG. 4 is a sectional view showing the concrete configuration of the aforementioned switching element 18.

Each switching element 18 includes a top gate electrode 21 illustrated in a protruding shape in the plan view of FIG. 3, a silicon layer SL provided as a semiconductor layer below this top gate electrode 21, and a bottom gate electrode 23 provided below the silicon layer SL and illustrated in an indented shape in the plan view of FIG. 3. That is, the switching element 18 is configured by a thin-film transistor of a double-gate structure having a top gate electrode 21 and a bottom gate electrode 23.

The top gate electrode 21 includes a parallel extension portion 21a that extends parallel to the gate wiring lines G and a vertical extension portion 21b that extends, in the central portion in the direction of length of the parallel extension portion 21a (in the left-right direction in FIG. 3), in the direction of width of the parallel extension portion 21a (in the up-down direction in FIG. 3), i.e., in a direction perpendicular to the gate wiring lines G. Consequently, the top gate electrode 21 is formed in a protruding shape, namely, in a shape similar to an inverted alphabet letter “T.”

The bottom gate electrode 23 presents a rectangular shape as a whole and has a rectangular cutout portion 23a that is smaller than the vertical extension portion 21b of the top gate electrode 21 in a position overlapping with the vertical extension portion 21b. This makes the bottom gate electrode 23 in an indented shape, namely, in a shape similar to an alphabet letter “U.”

Furthermore, in the switching element 18, the top gate electrode 21 and the bottom gate electrode 23 are provided so as to overlap with each other in the up-down direction (in the direction of thickness of the active matrix substrate 5). Consequently, the top gate electrode 21 and the bottom gate electrode 23 are capacitively coupled. Then, in each of the states of the switching element 18, i.e., in an ON state and OFF state, when the potential of the top gate electrode 21 is controlled by the application of voltage to the corresponding gate wiring line G, the potential of the bottom gate electrode 23 is designed to be set at a specified optimal potential in accordance with the capacitance coupling with the top gate electrode 21 (a detail to be described later).

Moreover, the bottom gate electrode 23 is configured so as to function as a light-shielding film as well which shields light from below the switching element 18, e.g., illumination light from the backlight device 3. In addition, as will be described in detail later, this bottom gate electrode 23 is provided below regions of the silicon layer SL that become depletion regions. Then, the bottom gate electrode 23 is designed such that the ON current (current drive power) of the switching element 18 is increased when controlled to an optimal potential in an ON state. Furthermore, the bottom gate electrode 23 is designed such that the (OFF) leak current of the switching element 18 is reduced when controlled to an optimal potential in an OFF state.

In addition, as is shown in FIG. 4, the switching elements 18 are provided in pixel units on the substrate main body 5a composed of a glass substrate, for example, in the active matrix substrate 5. That is, in each switching element 18, the aforementioned bottom gate electrode 23 is formed on the substrate main body 5a. Furthermore, a base coat film 34 is formed so as to cover this bottom gate electrode 23. Note that the substrate main body 5a can also be configured using a quartz substrate or plastic substrate besides the aforementioned description.

Moreover, in the switching element 18, the aforementioned silicon layer SL is formed on the base coat film 34. Then, a gate insulating film 35 is formed so as to cover this silicon layer SL. A source region 24, a low-concentration impurity region (LDD region: lightly doped drain region) 25, a channel region 26, a low-concentration impurity region 27, and a drain region 28 are formed in the silicon layer SL along the left-right direction in FIG. 4. Here, an n-type transistor, for example, is used for this switching element 18. Therefore, the source region 24 and the drain region 28 are configured from high-concentration regions (indicated by cross-hatching in FIG. 4) into which an n-type impurity, e.g., phosphorus, is implanted at a high concentration in the silicon layer SL. The low-concentration impurity regions 25 and 27 are configured from regions (indicated by dots in FIG. 4) into which an n-type impurity is implanted at a low concentration. Furthermore, the channel region 26 is configured from a region into which a p-type impurity, e.g., boron, is implanted.

Note that besides the aforementioned description, the switching element 18 may also be configured using a p-type transistor. In the case of using a p-type transistor, the source region 24, low-concentration impurity regions 25 and 27, and drain region 28 are configured from regions into which a p-type impurity is implanted. The channel region 26 is configured from a region into which an n-type impurity is implanted.

Moreover, besides the aforementioned description, the low-concentration impurity regions 25 and 27 may also be formed as p-type regions of the same concentration as in the channel region 26. That is, the low-concentration impurity regions 25 and 27 and the channel region 26 may also be formed as offset regions doped with a p-type impurity.

In addition, in the switching element 18, as is shown in FIG. 4, the bottom gate electrode (light-shielding film) 23 is provided below the low-concentration impurity regions 25 and 27, a portion of the source region 24, a portion of the drain region 28, and portions of the channel region 26 toward the low-concentration impurity regions 25 and 27, which includes the aforementioned depletion regions of the silicon layer SL. To described this in detail, one of the two protruding portions of the bottom gate electrode 23 illustrated in an indented shape in the plan view of FIG. 3 is provided below a portion of the source region 24, the low-concentration impurity region 25, and a portion of the channel region 26 on the side of the low-concentration impurity region 25. The other of the two protruding portions is provided below a portion of the channel region 26 on the side of the low-concentration impurity region 27, the low-concentration impurity region 27, and a portion of the drain region 28.

In the switching element 18, furthermore, the aforementioned top gate electrode 21 is formed on the gate insulating film 35 in a position directly above the channel region 26. Then, an interlayer insulating film 36 is formed so as to cover the top gate electrode 21. Moreover, the top gate electrode 21 is connected to the corresponding gate wiring line G (FIG. 3) via the gate electrode 31 formed on contact holes 22 and the interlayer insulating film 36 in the switching element 18. In addition, the source region 24 is connected to a source electrode 32 via contact holes 29. The drain region 28 is connected to a drain electrode 33 via contact holes 30. Such a source electrode 32 and drain electrode 33 are each connected to the corresponding source wiring line S (FIG. 2) and pixel electrode 19 (FIG. 2).

Note that besides the aforementioned description, a configuration is also possible in which the gate electrode 31 is not provided, and a conductive layer of the same material as the top gate electrode 21 is directly used as a gate wiring line G.

Furthermore, the potential of the top gate electrode 21 is controlled by a gate signal from the gate wiring line G in the switching element 18 as described above. The potential of the bottom gate electrode 23 is controlled by capacitance coupling with the top gate electrode 21.

Moreover, at the bottom gate electrode 23, when the switching element (thin-film transistor) 18 is in on OFF state, the potential of this bottom gate electrode 23 is controlled to be a specified optimal potential such that the low-concentration impurity regions 25 and 27 are in the depletion state. In concrete terms, the potential of the bottom gate electrode 23 is controlled at a voltage so as to have a ratio of 0.2 to 0.6 times with respect to the potential of the top gate electrode 21. Consequently, the leak current can be reliably reduced using the channel region 26 and the low-concentration impurity regions 25 and 27 in the switching element 18.

In addition, at the bottom gate electrode 23, when the switching element 18 is in an ON state, the potential of this bottom gate electrode 23 is controlled to be a specified optimal potential such that the low-concentration impurity regions 25 and 27 are in the accumulation state. In concrete terms, the potential of the bottom gate electrode 23 is controlled at a voltage so as to have a ratio of 0.2 to 0.6 times with respect to the potential of the top gate electrode 21. Consequently, the ON current can be reliably increased using the channel region 26 and the low-concentration impurity regions 25 and 27 in the switching element 18.

Furthermore, in each of the states of the switching element 18, i.e., in an ON state and OFF state, the specified optimal potential set for the bottom gate electrode 23 is appropriately determined based on the impurity concentration in the low-concentration impurity regions 25 and 27, the potential at the drain electrode 33, the potential at the top gate electrode 21 (voltage applied to the gate wiring line G), the film quality and thickness of the base coat film 34, and/or the capacitance coupling ratio in the portion where the top gate electrode 21 and the bottom gate electrode 23 are capacitively coupled, and the like.

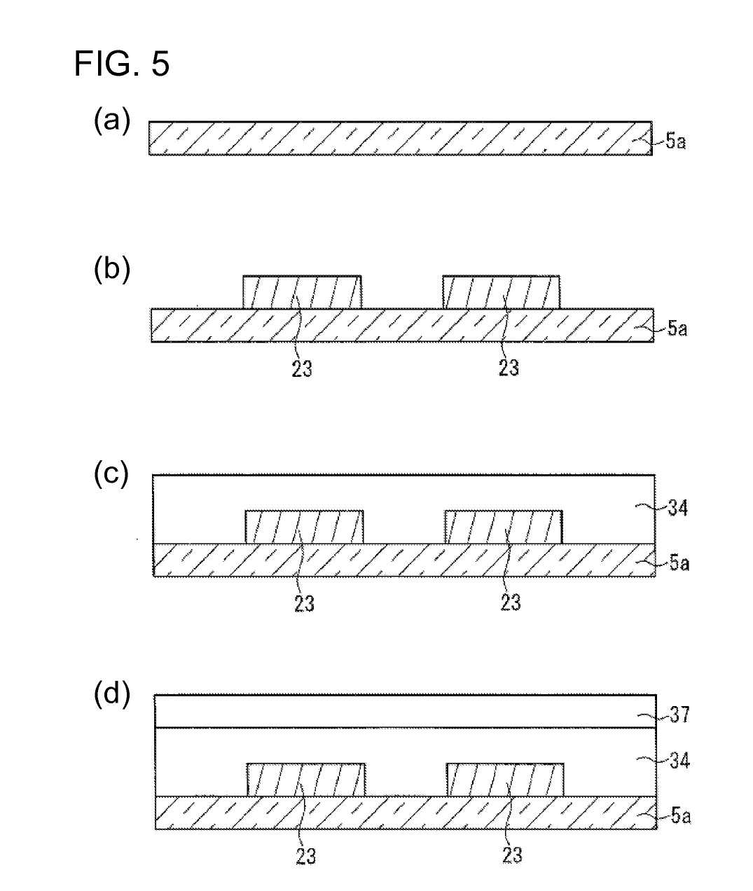

Here, a method for manufacturing a switching element 18 will be described specifically with reference to FIGS. 5 to 8.

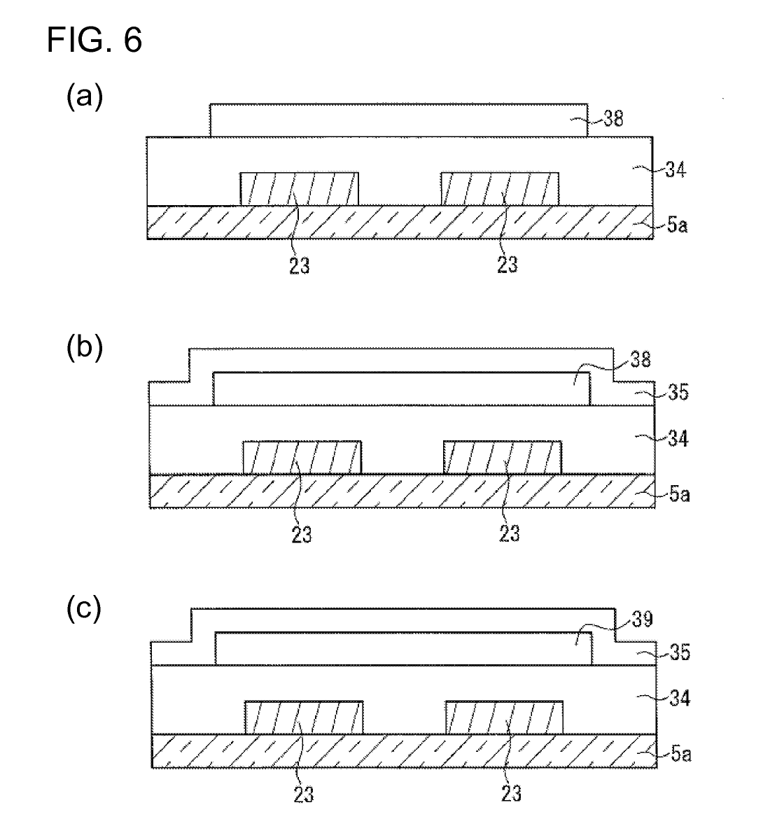

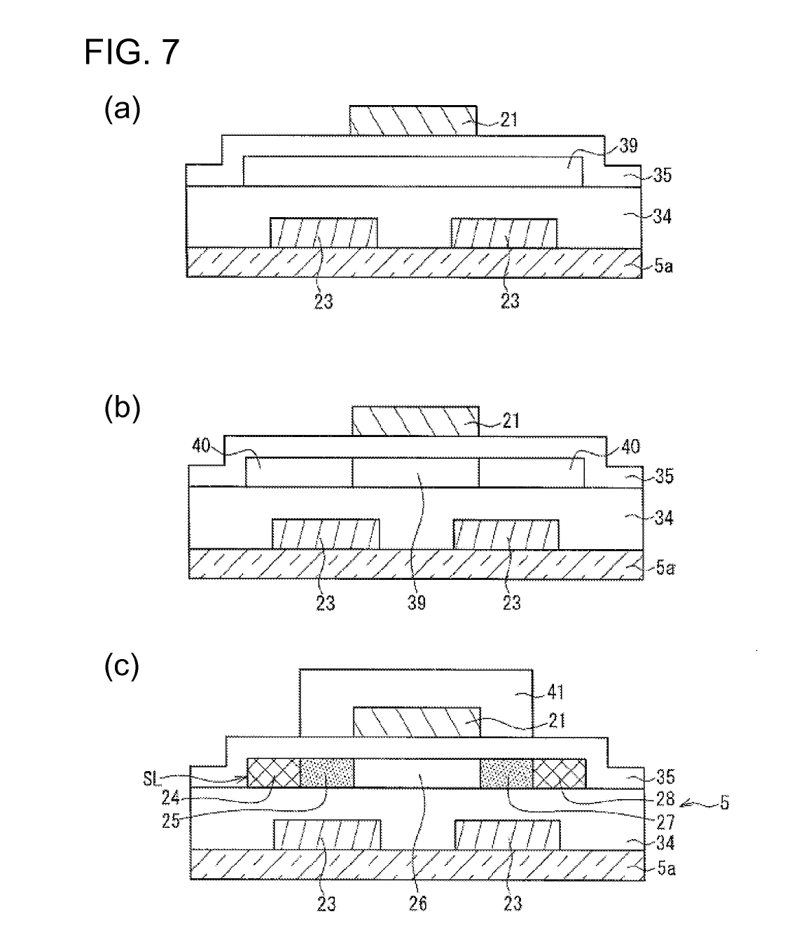

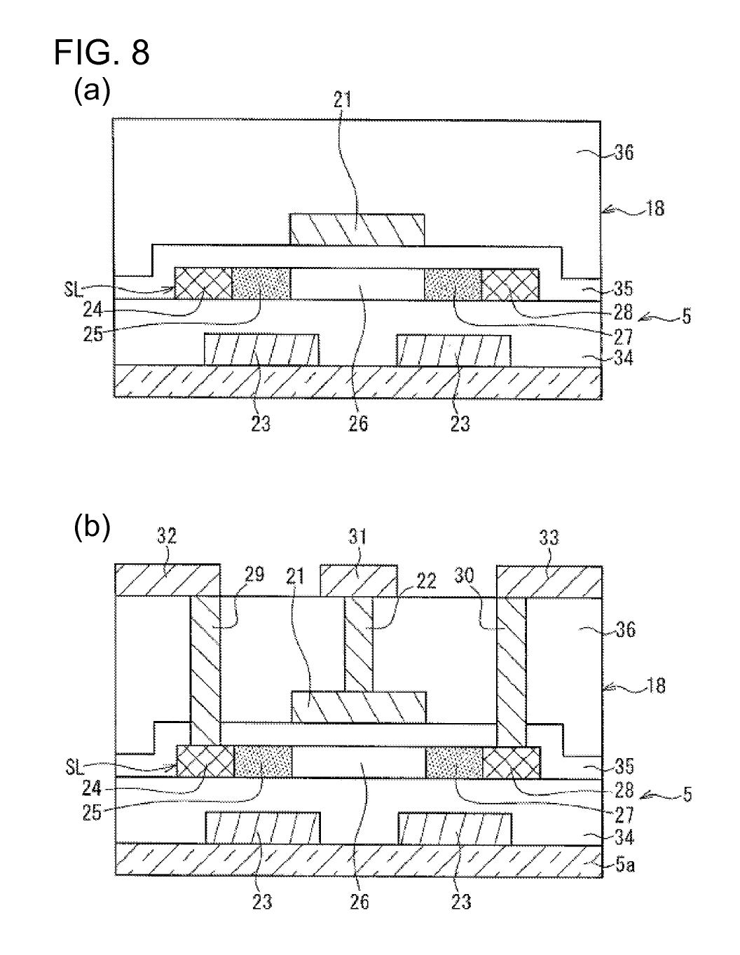

FIG. 5 constitutes a diagram illustrating manufacturing steps of the aforementioned switching element 18; FIGS. 5(a) to 5(d) illustrate a series of main manufacturing steps. FIG. 6 constitutes a diagram illustrating manufacturing steps of the aforementioned switching element 18; FIGS. 6(a) to 6(c) illustrate a series of main manufacturing steps performed following the completion of the step shown in FIG. 5(d). FIG. 7 constitutes a diagram illustrating manufacturing steps of the aforementioned switching element 18; FIGS. 7(a) to 7(c) illustrate a series of main manufacturing steps performed following the completion of the step shown in FIG. 6(c). FIG. 8 constitutes a diagram illustrating manufacturing steps of the aforementioned switching element 18; FIGS. 8(a) and 8(b) illustrate a series of main manufacturing steps performed following the completion of the step shown in FIG. 7(c).

As is shown in FIGS. 5(a) and 5(b), in the switching element 18, a bottom gate electrode 23 used as a light-shielding film as well is first formed on a substrate main body 5a. A conductive film in which a TaN film and a W film are laminated, for example, is used for this bottom gate electrode 23. Specifically, the aforementioned conductive film having a film thickness of 50 to 150 nm is formed on the substrate main body 5a and patterned by a photolithography method, i.e., the aforementioned conductive film is etched using a resist pattern formed on the aforementioned conductive film as the mask, thus forming the bottom gate electrode 23 having an indented shape as seen from the direction of thickness of the active matrix substrate 5.

Note that besides the aforementioned description, the aforementioned conductive film may also be formed from an element selected from among Ta, W, Ti, Mo, Al, Cu, Cr, Nd, and the like or an alloy material or compound material having the aforementioned element as the main component. Furthermore, it is also possible to form the aforementioned conductive film from a semiconductor film typified by polysilicon or the like doped with an impurity such as boron.

Next, as is shown in FIG. 5(c), a base coat film 34 is formed so as to cover the entire surfaces of the bottom gate electrode 23 and substrate main body 5a. Film made of an insulating inorganic substance such as a silicon oxide film, silicon nitride film, or silicon nitride oxide film, or a laminated film appropriately combining these can be used for this base coat film 34. In the present embodiment, a silicon oxide film is used. Moreover, the aforementioned film constituting the base coat film 34 can be formed by deposition using an LPCVD method, plasma CVD method, sputtering method, or the like. In addition, for the thickness of the base coat film 34, an optimal film thickness is required which takes into account that the silicon layer SL must be planarized as much as possible and that the electric field effect of the bottom gate electrode is obtained. In concrete terms, the thickness of the base coat film 34 is set at approximately 100 to 500 nm.

Subsequently, a non-single-crystalline semiconductor thin film 37 is formed so as to cover the entire surface of the base coat film 34 as shown in FIG. 5(d). This non-single-crystalline semiconductor thin film 37 is formed by an LPCVD method, plasma CVD method, sputtering method, or the like. For the non-single-crystalline semiconductor thin film 37, amorphous silicon, polycrystalline silicon, amorphous germanium, polycrystalline germanium, amorphous silicon germanium, polycrystalline silicon germanium, amorphous silicon carbide, polycrystalline silicon carbide, or the like can be used. In the present embodiment, amorphous silicon is used for the non-single-crystalline semiconductor thin film 37. Furthermore, the thickness of this non-single-crystalline semiconductor thin film 37 is related to the properties of the thin-film transistor and is set at approximately 30 to 80 nm, for example.

Next, the non-single-crystalline semiconductor thin film 37 is irradiated with a laser beam, electron beam, or the like to crystallize this non-single-crystalline semiconductor thin film 37, thus forming a polycrystalline semiconductor thin film 38. Afterward, as is shown in FIG. 6(a), patterning is performed on this polycrystalline semiconductor thin film 38 by a photolithography method in accordance with the region in which the bottom gate electrode 23 is formed.

Subsequently, as is shown in FIG. 6(b), a gate insulating film 35 is formed so as to cover the entire surfaces of the polycrystalline semiconductor thin film 38 and base coat film 34. This gate insulating film 35 is made of an inorganic insulating film such as a silicon oxide film and silicon nitride film, or a laminated film of these. Moreover, the thickness of the gate insulating film 35 is set at approximately 30 to 80 nm, for example.

Next, doping of a p-type impurity such as boron is performed from above the gate insulating film 35. Consequently, a p-type channel region 39 is formed as shown in FIG. 6(c). Afterward, a TaN film and a W film, for instance, are laminated as the conductive film on the gate insulating film 35. Note that a film in which a TaN film and a W film are laminated is used as the aforementioned conductive film in the present embodiment. However, the aforementioned conductive film is not limited to the laminated structure of the TaN film and W film. The aforementioned conductive film may also be formed from an element selected from among Ta, W, Ti, Mo, Al, Cu, Cr, Nd, and the like or an alloy material or compound material having the aforementioned element as the main component. In addition, it is also possible to form the aforementioned conductive film from a semiconductor film typified by polycrystalline silicon or the like doped with an impurity such as boron.

Then, as is shown in FIG. 7(a), patterning is performed on the aforementioned conductive film using a photolithography method, i.e., the aforementioned conductive film is etched using a resist pattern formed in the form of the aforementioned conductive film as the mask, thus forming a top gate electrode 21 on the gate insulating film 35. The thickness of this top gate electrode 21 is set at approximately 200 to 600 nm, for example.

Subsequently, doping of an n-type impurity such as phosphorus is performed from above the gate insulating film 35 at a relatively low concentration so as to be self-aligned with the top gate electrode 21. Consequently, low-concentration impurity regions 40 are formed so as to sandwich the p-type channel region 39 as shown in FIG. 7(b).

Next, a photoresist 41 is formed on the gate insulating film 35, after which doping of an n-type impurity such as phosphorus is performed from above the gate insulating film 35. Consequently, a source region 24, a drain region 28, low-concentration impurity regions 25 and 27, and a channel region 26 are formed as shown in FIG. 7(c).

Subsequently, as is shown in FIG. 8(a), an interlayer insulating film 36 is formed so as to cover the entire surfaces of the top gate electrode 21 and gate insulating film 35. This interlayer insulating film 36 is made of an inorganic insulating film such as a silicon oxide film or silicon nitride film or a laminated film of these. Furthermore, the thickness of the interlayer insulating film 36 is set at approximately 500 to 1500 nm, for example.

Afterward, as is shown in FIG. 8(b), contact holes 29 and 30 that pass through the gate insulating film 35 and the interlayer insulating film 36 are formed above the source region 24 and the drain region 28, respectively. Moreover, contact holes 22 that pass through the interlayer insulating film 36 are formed above the top gate electrode 21. Then, a conductive film is formed on the interlayer insulating film 36 by a sputtering method or the like. A conductive film composed of aluminum or the like, for instance, can be used as this conductive film but is not limited to this. It is also possible to form the conductive film using an element selected from among Ta, W, Ti, Mo, Al, Cu, Cr, Nd, and the like or an alloy material or compound material having the aforementioned element as the main component or to form the conductive film having a laminated structure by appropriately combining these as needed. In the present embodiment, aluminum is used.

Finally, a gate electrode 31, a source electrode 32, and a drain electrode 33 are formed on the interlayer insulating film 36 by performing patterning on the aforementioned conductive film in a desired shape by a photolithography method. In addition, the respective film thicknesses of the gate electrode 31, source electrode 32, and drain electrode 33 are set at approximately 250 to 800 nm, for instance.

In the switching element (semiconductor device) 18 of the present embodiment configured as described above, the silicon layer (semiconductor layer) SL having the source region 24, drain region 28, channel region 26, and low-concentration impurity regions 25 and 27 is provided between the top gate electrode 21 and the bottom gate electrode (light-shielding film) 23. Furthermore, the bottom gate electrode 23 is provided below regions of the silicon layer SL that become depletion regions. Specifically, in the switching element 18 of the present embodiment, unlike the aforementioned prior art, the bottom gate electrode 23 is provided only below junction regions (carrier generation regions) that induce (OFF) leak current due to photoelectric effect so as to shield the light from the silicon layer SL. Moreover, at the bottom gate electrode 23, the potential of the bottom gate electrode 23 is controlled so as to be a specified potential. Consequently, in the present embodiment, unlike the aforementioned conventional example, it is possible to configure a switching element 18 which can achieve an increase in ON current and which can also achieve a reduction in leak current.

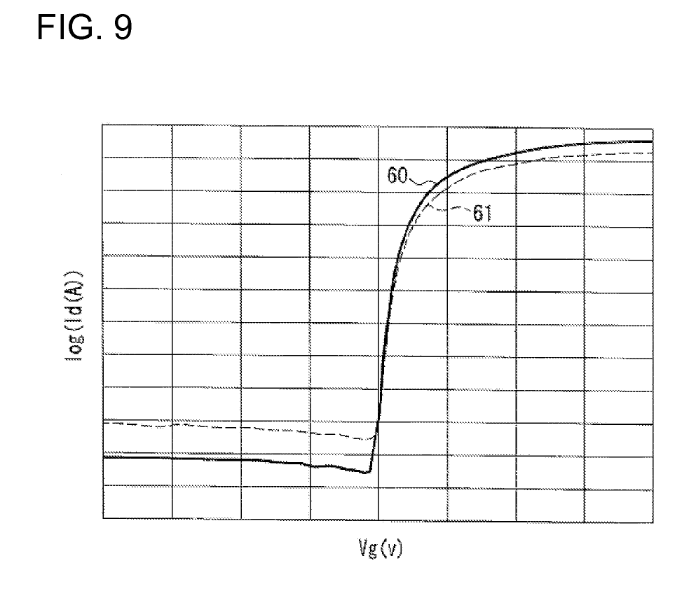

Here, the aforementioned effect in the switching element 18 of the present embodiment will be described in concrete terms using FIG. 9.

FIG. 9 is a graph showing the relationship between the top gate voltage and the drain current in a working example of the present embodiment and in a conventional product.

In order to verify the aforementioned effect in the switching element 18 of the present embodiment, the inventor of the invention of the present application prepared a working example of the present embodiment and a conventional product corresponding to the aforementioned conventional example and actually measured the ON currents and leak currents. One example of the results of this verification test is shown in FIG. 9.

In the working example of the present embodiment, when the top gate voltage is greater than 0V, i.e., when the switching element 18 is in an ON state, the potential of the bottom gate electrode 23 is set at the optimal potential for the ON state by the capacitance coupling with the top gate electrode 21 as described above. It was confirmed that the drain current, i.e., ON current, was therefore increased with the working example of the present embodiment as indicated by the solid line 60 in FIG. 9 than with the conventional product indicated by the dotted line 61 in FIG. 9.

In addition, in the working example of the present embodiment, when the top gate voltage is 0V or less, i.e., when the switching element 18 is in an OFF state, the potential of the bottom gate electrode 23 is set at the optimal potential for the OFF state by the capacitance coupling with the top gate electrode 21 as described above. It was confirmed that the drain current, i.e., leak current, was therefore reduced with the working example of the present embodiment as indicated by the solid line 60 in FIG. 9 than with the conventional product indicated by the dotted line 61 in FIG. 9.

In the present embodiment, furthermore, the bottom gate electrode 23 is provided below the low-concentration impurity regions 25 and 27, a portion of the source region 24, a portion of the drain region 28, and portions of the channel region 26 toward the low-concentration impurity regions 25 and 27, which are the depletion regions. Consequently, it becomes possible to prevent these depletion regions from being irradiated with light. As a result, the leak current can be reliably reduced.

Moreover, in the present embodiment, the potential of the top gate electrode 21 is controlled by a gate signal from a gate wiring line (first signal wiring) G connected to the top gate electrode 21, and the potential of the bottom gate electrode 23 is controlled by the capacitance coupling with the top gate electrode 21. Consequently, in the present embodiment, it is possible to omit the installation of a signal wiring line or the like for applying a specified potential to the bottom gate electrode 23. As a result, a switching element 18 with a simple structure can be configured easily.

In addition, in the present embodiment, at the bottom gate electrode 23, when the switching element 18 is in an OFF state, the potential of this bottom gate electrode 23 is controlled such that the low-concentration impurity regions 25 and 27 are in the depletion state, and when the switching element 18 is in an ON state, the potential of this bottom gate electrode 23 is controlled such that the low-concentration impurity regions 25 and 27 are in the accumulation state. Consequently, in the present embodiment, it is possible to reliably achieve a reduction in leak current and also to reliably achieve an increase in ON current.

In the present embodiment, furthermore, because a switching element (semiconductor device) 18 is used which can increase the ON current and which can also reduce the leak current, it is possible to easily configure an active matrix substrate 5 and a liquid crystal display device (display device) 1 with high performance and lower power consumption.

### Second Embodiment

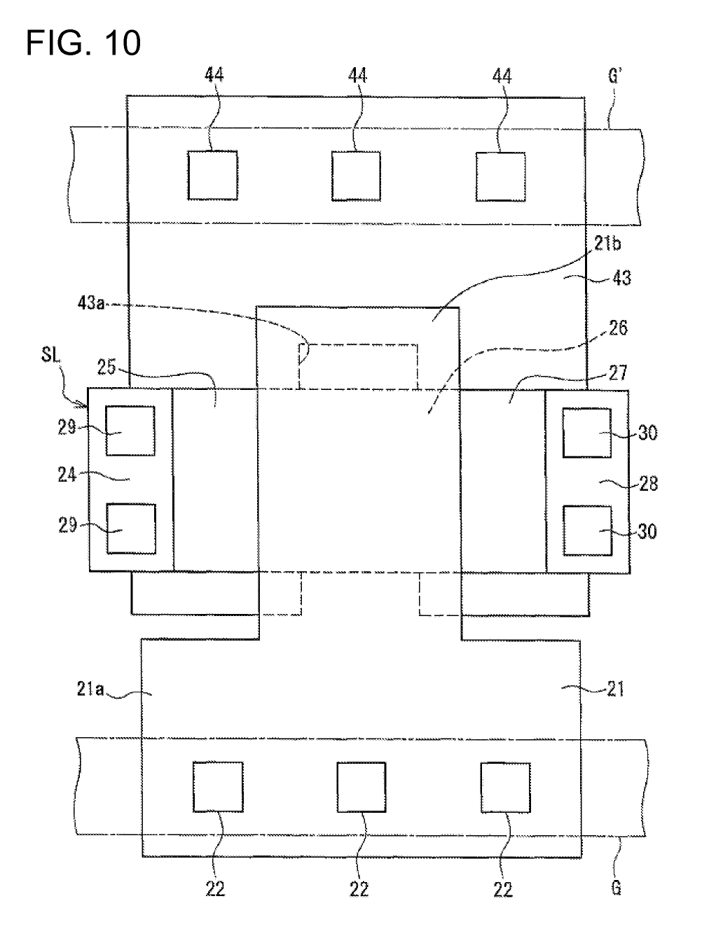

FIG. 10 is a plan view showing the configuration of principal parts of the switching element according to a second embodiment of the present invention. In FIG. 10, the main differences between the present embodiment and the aforementioned first embodiment are that a bottom gate wiring line (second signal wiring) is connected to the bottom gate electrode and that the potential of the bottom gate electrode is controlled by a bottom gate signal from the bottom gate wiring line. Note that the elements that are common to the aforementioned first embodiment are assigned the same reference characters, and a redundant description thereof is omitted.

Specifically, in the switching element of the present embodiment, the bottom gate electrode 43 illustrated in an indented shape in the plan view of FIG. 10 is provided such that this bottom gate electrode 43 and the top gate electrode 21 illustrated in a protruding shape in the plan view of FIG. 10 face each other in the up-down direction in FIG. 10. The bottom gate electrode 43 presents a rectangular shape as a whole and has a rectangular cutout portion 43a that is smaller than the vertical extension portion 21b of the top gate electrode 21 in a portion located below the vertical extension portion 21b. This makes the bottom gate electrode 43 a shape similar to an inverted alphabet letter “U.” Furthermore, this bottom gate electrode 43, unlike the one in the first embodiment, is provided so as to avoid mutual overlapping with the top gate electrode 21 as much as possible in the up-down direction (in the direction of thickness of the active matrix substrate 5). As a result, the bottom gate electrode 43 and the top gate electrode 21 are formed such that capacitance coupling does not occur.

Moreover, a bottom gate wiring line G′ as second signal wiring is connected to the bottom gate electrode 43 via contact holes 44. This bottom gate wiring line G′ is provided so as to be parallel to the gate wiring lines G and is connected to the gate driver 17 in the same way as the gate wiring lines G. Then, at the switching element of the present embodiment, in each of the states thereof, i.e., in an ON state and OFF state, a bottom gate signal (application of voltage) to the bottom gate wiring line G′ is controlled such that the potential of the bottom gate electrode 43 is at a specified optimal potential in a manner similar to the first embodiment.

With the above configuration, actions and effects similar to those of the aforementioned first embodiment can be manifested in the present embodiment. In addition, the potential of the bottom gate electrode 43 is controlled by the bottom gate signal from the bottom gate wiring line (second signal wiring) G′ connected to the bottom gate electrode 43 in the present embodiment. Consequently, control can be performed with a higher degree of freedom with respect to the potential of this bottom gate electrode 43. As a result, it is possible to achieve an increase in ON current and a reduction in leak current more easily.

Note that all of the aforementioned embodiments are examples and are not restrictive. The technological scope of the present invention is defined by the scope of the claims, and all modifications within a range equivalent to the configurations described therein shall also be included in the technological scope of the present invention.

For example, the aforementioned description was given by exemplifying a case in which the present invention is applied to switching elements for pixel electrodes used in the active matrix substrate of a liquid crystal display device. However, there is no limitation in any way on the semiconductor device of the present invention as long as it includes a semiconductor layer provided between the top gate electrode and the bottom gate electrode and having a source region, a drain region, and a channel region, and the bottom gate electrode is provided below regions of the semiconductor layer that become depletion regions, with the potential of the bottom gate electrode being controlled so as to be a specified magnitude. In concrete terms, for example, the semiconductor device of the present invention can be applied to various types of display device, such as transflective or reflective liquid crystal panels, organic electronic luminescence (EL) elements, inorganic EL elements, and field emission displays, as well as active matrix substrates used for these devices and the like. Furthermore, besides switching elements for pixel electrodes, the semiconductor device of the present invention can be applied to switching elements used in peripheral circuits such as driver circuits.

Moreover, in the aforementioned description, a case was described in which the bottom gate electrode is used as a light-shielding film, but the present invention is not limited to this in any way. In concrete terms, it is also possible to use a configuration in which a bottom gate electrode is configured using a transparent electrode, and a light-shielding film is provided below the bottom gate electrode below the semiconductor layer. A configuration is also possible which is provided with a bottom gate electrode and a light-shielding film below this bottom gate electrode using the same electrode material as the bottom gate electrode.

However, the case of doubling the bottom gate electrode as a light-shielding film as in each of the aforementioned embodiments is preferable in that it is possible to prevent the structure of the semiconductor device from becoming complex and larger in size and also to easily configure a semiconductor device that is simple to manufacture.

In addition, in the aforementioned description, a case was described in which a single thin-film transistor is used as the switching element for a pixel electrode, but the present invention is not limited this. It is also possible to use a plurality of thin-film transistors connected in series as the switching unit for the aforementioned pixel electrode, for example.

### INDUSTRIAL APPLICABILITY

The present invention is useful for a semiconductor device which can achieve an increase in ON current and which can also achieve a reduction in leak current, as well as an active matrix substrate and a display device using such a semiconductor device.

1. A semiconductor device comprising a thin-film transistor having a top gate electrode and a bottom gate electrode, wherein
a semiconductor layer is provided between said top gate electrode and said bottom gate electrode, and has a source region, a drain region, and a channel region,
said bottom gate electrode is provided below a region of said semiconductor layer that is to become a depletion region, and
a potential of said bottom gate electrode is controlled so as to be within a specified range.

2. The semiconductor device according to claim 1, wherein said bottom gate electrode has a light shielding property.

3. The semiconductor device according to claim 1, wherein
low-concentration impurity regions are respectively provided in said semiconductor layer between said source region and said channel region and between said channel region and said drain region, and
said bottom gate electrode is provided below said low-concentration impurity regions, a portion of said source region, a portion of said drain region, and portions of said channel region toward said low-concentration impurity regions, which are to become said depletion regions.

4. The semiconductor device according to claim 3, wherein
at said bottom gate electrode, the potential of the bottom gate electrode is controlled such that said low-concentration impurity region is in a depletion state when said thin-film transistor is in an OFF state, and
the potential of the bottom gate electrode is controlled such that said low-concentration impurity region is in an accumulation state when said thin-film transistor is in an ON state.

5. The semiconductor device according to claim 1, wherein
at said top gate electrode, the potential of the top gate electrode is controlled by a gate signal from first signal wiring connected to the top gate electrode, and
at said bottom gate electrode, the potential of the bottom gate electrode is controlled by capacitance coupling with said top gate electrode.

6. The semiconductor device according to claim 1, wherein
at said top gate electrode, the potential of the top gate electrode is controlled by a gate signal from first signal wiring connected to the top gate electrode, and
at said bottom gate electrode, the potential of the bottom gate electrode is controlled by a bottom gate signal from second signal wiring connected to the bottom gate electrode.

7. An active matrix substrate using the semiconductor device according to claim 1.

8. A display device using the semiconductor device according to claim 1.
